(19) United States
(12) Patent Application Publication
(10) Pub. No.: US 2024/0378327 A1
(43) Pub. Date: Nov. 14, 2024

(54) MATERIAL PROCESSING MODELING

(71) Applicant: Taiwan Semiconductor Manufacturing Company Limited, Hsin-Chu (TW)

(72) Inventors: Danping PENG, Fremont, CA (US); Nuo XU, San Jose, CA (US)

(21) Appl. No.: 18/144,277

(22) Filed: May 8, 2023

(51) Int. Cl. G06F 30/12

(52) U.S. Cl. CPC G06F 30/12; H01L 29/66439

(57) ABSTRACT

Among other things, one or more techniques for simulating a process operation of a process tool are provided. In an embodiment, a voxel mesh is defined to represent a structure and a conformal surface mesh is defined for the voxel mesh. Direction dependent rates are determined for voxels in the voxel mesh using the conformal surface mesh. The voxel mesh is updated based on the direction dependent rates. The defining of the conformal surface mesh, the determining of the direction dependent rates, and the updating of the voxel mesh are iterated to simulate the process operation. A parameter of the voxel mesh is determined after simulating the process operation.

### BACKGROUND

Technology Computer Aided Designs (TCAD) tools aim to use physics-based models and computer simulations to quantitatively evaluate semiconductor devices, processes, and material properties. These tools are used to predict experimental results or trends without requiring the fabrication of physical devices to reduce development cycles and save resources.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of a fabrication system, in accordance with some embodiments.

FIG. 2 is a diagram illustrating a voxel mesh.

FIG. 3 is a diagram illustrating a conformal surface mesh, in accordance with some embodiments.

FIG. 4 is a diagram illustrating a surface generated for a voxel, in accordance with some embodiments.

FIG. 5 is a diagram illustrating crystalline directions, in accordance with some embodiments.

FIG. 6 is a diagram illustrating voxel growth, in accordance with some embodiments.

FIGS. 7 and 8 are diagrams illustrating simulation of material growth using Lax-Friedrichs and weighted essentially non-oscillatory scheme correction adjustments for edge regions, in accordance with some embodiments.

FIGS. 9A-9G are illustrations of a semiconductor arrangement at various stages of fabrication, in accordance with some embodiments.

FIGS. 10 and 11 are diagrams illustrating epitaxial structures, in accordance with some embodiments.

FIG. 12 is a flow diagram of an example method for simulating material processing, in accordance with some embodiments.

FIG. 13 is an illustration of an example computer-readable medium wherein processor-executable instructions configured to embody one or more of the provisions set forth herein may be comprised, in accordance with some embodiments.

FIG. 14 is a diagram of a computing environment to implement embodiments of one or more of the provisions set forth herein, in accordance with some embodiments.

### DETAILED DESCRIPTION

The following disclosure provides many different embodiments, or examples, for implementing different features of the provided subject matter. Specific examples of components and structures are described below to simplify the present disclosure. These are, of course, merely examples and are not intended limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to some embodiments, a fabrication simulator is used to simulate the processing of a layer, such as a crystalline layer. The fabrication simulator uses a voxel mesh to simulate material processing. The material processing simulation by the fabrication simulator allows at least one of operating recipe parameters or control parameters to be determined for one or more process tools without requiring device fabrication and metrology. The fabrication simulator may use a Hamilton-Jacobi solving technique on the voxel mesh to simulate processing.

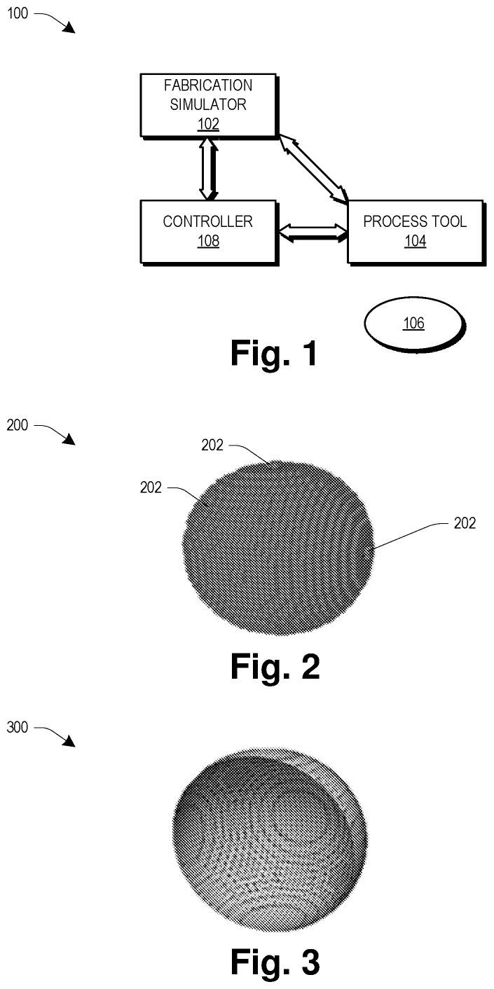

FIG. 1 is a diagram of a fabrication system 100, in accordance with some embodiments. In some embodiments, the fabrication system 100 comprises a fabrication simulator 102 that simulates operation of a process tool 104 for performing a process operation, such as a material addition process operation or a material removal process operation, on a semiconductor wafer 106. The process tool 104 may have an associated controller 108 that determines and updates an operating recipe used by the process tool 104 for fabricating the semiconductor wafer 106. In some embodiments, the controller 108 receives metrology data collected from previously fabricated semiconductor wafers 106 and modifies the operating recipe, for example, to change a process time, processing rate, endpoint, or some other parameter of the operating recipe to reduce variation from a target characteristic of the semiconductor wafer 106. The controller 108 may use control parameters associated with adjustment of the recipe, such as a weighting factor for discounting metrology data over time, a gain parameter used in a control loop for controlling the operating recipe parameter, or some other control parameter.

In some embodiments, the fabrication simulator 102 allows modeling of the physical process performed by the process tool 104 without requiring actual fabrication and metrology on the semiconductor wafer 106. Information generated by the fabrication simulator 102 may be used to at least one of determine an operating recipe parameter for the process tool 104 when fabricating the semiconductor wafer 106, estimate the effect of changing the operating recipe parameter of the process tool 104, or determine a control parameter for the controller 108 of the process tool 104. In some embodiments, the fabrication simulator 102 models a deposition process for forming epitaxial silicon on a semiconductor structure. The fabrication simulator 102 may model the growth of other crystalline materials, such as SiGe, Ge, SiC, GaAs, InGaAs, or some other crystalline material. The fabrication simulator 102 may model other types of deposition processes, such as atomic layer deposition (ALD), chemical vapor deposition (CVD), physical vapor deposition (PVD), sputtering, electro-coating, or some other deposition process. The fabrication simulator 102 uses a voxel mesh technique to model material processing. In some embodiments, the material processing is a growth process, such as a crystalline growth process or a deposition process. In some embodiments, the material processing is a removal process, such as an etch process.

Referring to FIG. 2, a diagram illustrating a voxel mesh 200 is provided, in accordance with some embodiments. An individual voxel 202 represents a cube of material, such as epitaxial silicon. The voxel mesh 200 is a set of voxels 202 in a 3D arrangement. The voxel mesh 200 approximates the physics-based diamond-type lattice that represents a crystalline structure. The fabrication simulator 102 models the material growth or removal as a continuous, rate dependent process.

Referring to FIG. 3, a diagram illustrating a conformal surface mesh 300 is provided, in accordance with some embodiments. Material growth or removal is dependent on direction. Since the voxel mesh 200 uses discrete voxels 202 with cubic structures, the fabrication simulator 102 adjusts the surface orientation used for direction dependent growth rate using the conformal surface mesh 300 to more accurately determine the surface orientation of a selected voxel 202 on the surface of the voxel mesh 200. Starting with the voxel mesh 200 in FIG. 2, interpolation is performed to generate a surface. For example, a marching cube interpolation constructs triangles to generate a polygonal mesh (e.g., using triangles) from a voxel mesh. In some embodiments, a local smoothing algorithm is performed after the interpolation to generate a smoother surface.

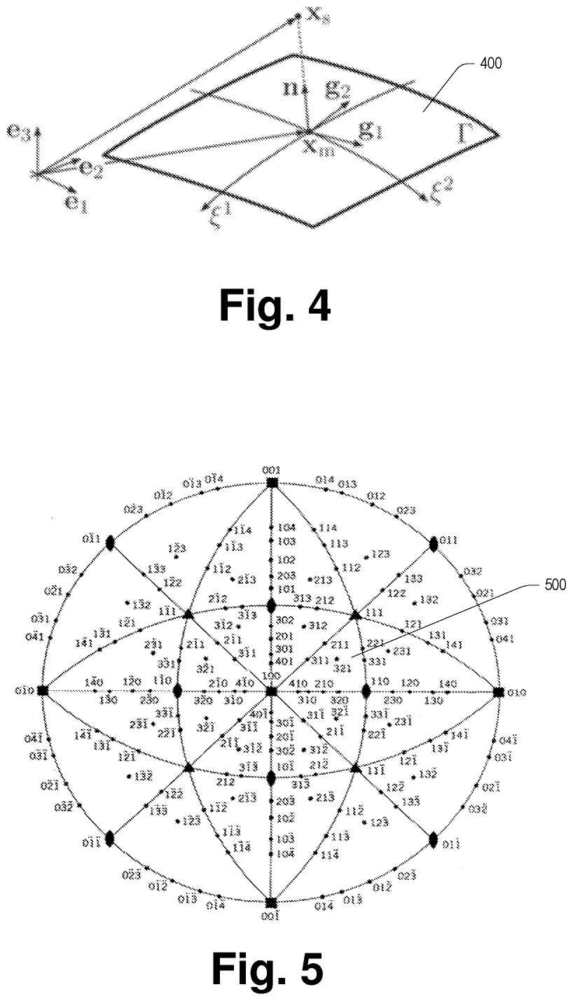

Referring to FIG. 4, a diagram illustrating a surface 400 generated for a voxel 202 is provided, in accordance with some embodiments. In some embodiments, the surface 400 is generated by interpolating and smoothing the voxel mesh 200. A surface normal direction is generated for the surface 400 to provide an input to the fabrication simulator 102 to update the voxel mesh 200. Given a regular grid point adjacent to a surface Γ, the orthogonal projection of x_{S} onto the surface Γ is defined as:

$${x}_{m} = {min}_{x ∈ Γ} \vert x - {x}_{S} \vert .$$

Referring to FIG. 5, a diagram illustrating crystalline directions is provided, in accordance with some embodiments. The surface normal direction determined using the conformal surface mesh 300 is used to determine the crystalline growth rate. Considering a segment 500 having crystalline direction vertices of 100, 111, and 110, the stereographic projection of the crystalline growth rate is:

$$RATE = \frac{ℋ ( 2 k + h - l )}{l} [ 2 {E}_{110} ( h - k ) + {E}_{111} ( h + 2 k - l ) + 3 {E}_{311} ( h - l ) ] + \frac{1 - ℋ ( 2 k + h - l )}{2 l} [ {E}_{100} ( l - h - 2 k ) + {E}_{110} ( h - k ) + 3 {E}_{311} k ] ,$$

where [symbol] (·) is the Heaviside function and h, k, and l are the normalized Miller indices.

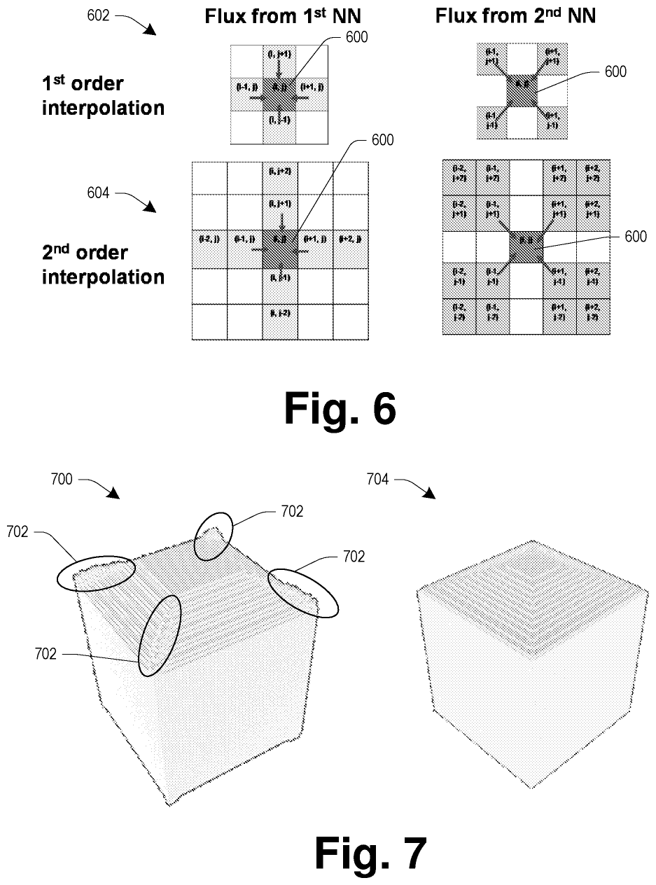

Referring to FIG. 6, a diagram illustrating voxel growth is provided, in accordance with some embodiments. In some embodiments, the fabrication simulator 102 employs a Hamilton-Jacobi solver on the voxel mesh 200 to update the growth rate. The conformal surface mesh 300 enhances the numerical stability of the solver since the surface normal direction is more accurate. Material growth is affected by the growth rate of the individual voxel 202 as well as contributions from neighboring voxels 202. A target voxel 600 is indexed as voxel (i, j) and neighboring voxels are indicated by adding or subtracting from the indices. In a first order interpolation 602, contributions to the target voxel 600 are received from the first nearest neighbor voxels and the second nearest neighbor voxels. In a second order interpolation 604, contributions to the target voxel 600 are also received from the voxels adjacent the first nearest neighbor voxels and the second nearest neighbor voxels. Two interpolations are shown in FIG. 6, but the number of interpolations used by the fabrication simulator 102 may vary, for example, more than two interpolations or less than two interpolations may be used by the fabrication simulator 102.

The Hamilton-Jacobi equation may be written as:

$$\frac{\partial φ}{\partial t} + H ( ∇ φ ) = 0.$$

Applying the Godunov theorem, the continuum partial differential equation (PDE) solution applying uniform spatial and numerical schemes is:

$${φ}_{j}^{n + 1} = {\sum }_{m}^{M} {γ}_{m} {φ}_{j + m}^{n} .$$

The growth equation for the target voxel 600 is:

$${φ}_{i , j}^{n + 1} = {φ}_{i , j}^{n} + {F}_{1 NN}^{m} [ {φ}_{i - 1 , j}^{n} , {φ}_{i + 1 , j}^{n} , ... , {φ}_{i - m , j}^{n} , {φ}_{i + m , j}^{n} , {φ}_{i , j - 1}^{n} , {φ}_{i , j + 1}^{n} , ... , {φ}_{i , j - m}^{n} , {φ}_{i , j + m}^{n} ] + {F}_{2 NN}^{m} [ \begin{matrix}{φ}_{i - 1 , j - 1}^{n} , ... , {φ}_{i - m , j - 1}^{n} , ... , {φ}_{i - m , j - m}^{n} , ... , {φ}_{i - 1 , j - m}^{n} \\ {φ}_{i + 1 , j - 1}^{n} , ... , {φ}_{i + m , j - 1}^{n} , ... , {φ}_{i + m , j - m}^{n} , ... , {φ}_{i + 1 , j - m}^{n} \\ {φ}_{i - 1 , j + 1}^{n} , ... , {φ}_{i - m , j + 1}^{n} , ... , {φ}_{i - m , j + m}^{n} , ... , {φ}_{i - 1 , j + m}^{n} \\ {φ}_{i + 1 , j + 1}^{n} , ... , {φ}_{i + m , j + 1}^{n} , ... , {φ}_{i + m , j + m}^{n} , ... , {φ}_{i + 1 , j + m}^{n}\end{matrix} ]$$

where m is the interpolation order and n is the voxel index.

The diagram illustrated in FIG. 6 is simplified for purposes of illustration. Contributions from voxels in the same plane (e.g., two-dimensional (2D)) are illustrated. The fabrication simulator 102 may determine contributions in three-dimensional (3D) space by expanding the rate equation using (i, j, k) indices and expanding the rate equation.

In some embodiments, the fabrication simulator 102 employs stability operations, such as one or more of a Lax-Friedrichs (LF) operation for edge regions, a weighted essentially non-oscillatory scheme (WENO) operation, or a total variance diminishing (TVD)² operation.

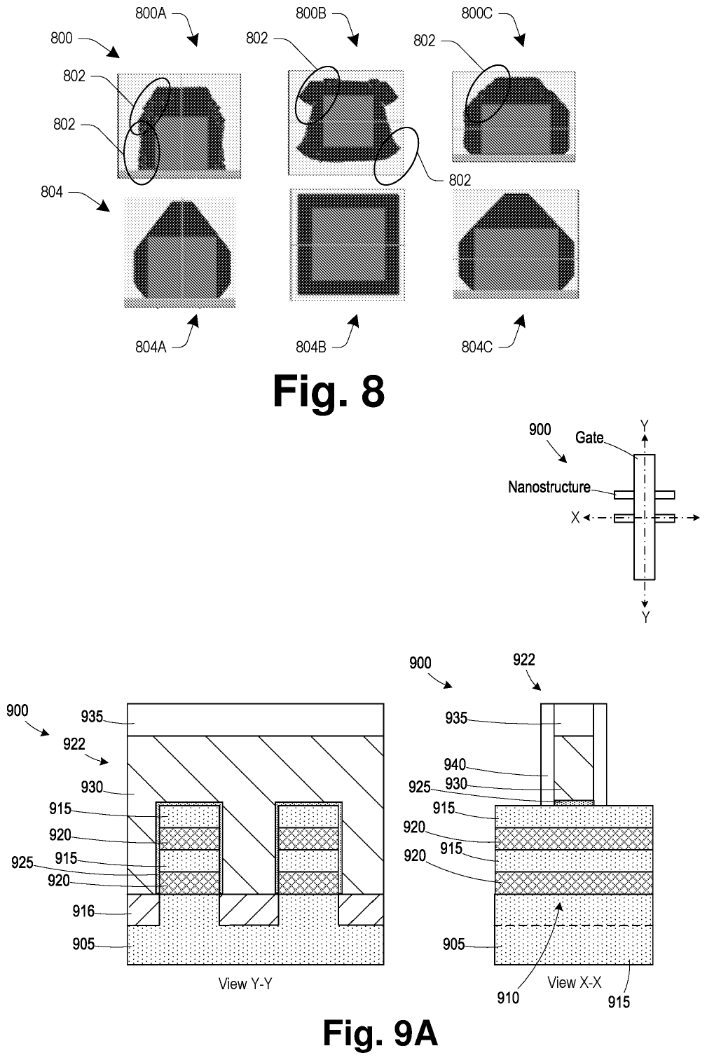

Referring to FIGS. 7 and 8, diagrams illustrating simulation of crystalline growth using Lax-Friedrichs and WENO operations for edge regions are provided, in accordance with some embodiments. According to a WENO flux definition:

$${Δ}^{+} {φ}_{k} = {φ}_{k + 1} - {φ}_{k} and {φ}_{k} = {φ}_{k} - {φ}_{k - 1}$$

$$\begin{matrix}{φ}_{x}^{+} = \frac{1}{2} ( \frac{{Δ}^{+} {φ}_{i - 1}^{n} + {Δ}^{+} {φ}_{i}^{n}}{Δ x} ) - \frac{{w}^{+}}{2} ( \frac{{Δ}^{+} {φ}_{i + 1}^{n} - 2 {Δ}^{+} {φ}_{i}^{n} + {Δ}^{+} {φ}_{i - 1}^{n}}{Δ x} ) {φ}_{x}^{-} \\ = \frac{1}{2} ( \frac{{Δ}^{+} {φ}_{i - 1}^{n} + {Δ}^{+} {φ}_{i}^{n}}{Δ x} ) - \frac{{w}^{-}}{2} ( \frac{{Δ}^{+} {φ}_{i - 2}^{n} - 2 {Δ}^{+} {φ}_{i - 1}^{n} + {Δ}^{+} {φ}_{i}^{n}}{Δ x} )\end{matrix}$$

$${w}^{+} = \frac{1}{1 + 2 {r}_{+}^{2}} , {r}_{+} = \frac{{( {Δ}^{-} {Δ}^{+} {φ}_{i + 1}^{n} )}^{2}}{{( {Δ}^{-} {Δ}^{+} {φ}_{i}^{n} )}^{2}} {w}^{-} = \frac{1}{1 + 2 {r}_{-}^{2}} , {r}_{-} = \frac{{( {Δ}^{-} {Δ}^{+} {φ}_{i - 1}^{n} )}^{2}}{{( {Δ}^{-} {Δ}^{+} {φ}_{i}^{n} )}^{2}}$$

The LF adjustment using the WENO flux is:

$${H}_{LF} ( {φ}_{x}^{+} , {φ}_{x}^{-} , {φ}_{y}^{+} , {φ}_{y}^{-} ) = H ( \frac{{φ}_{x}^{+} + {φ}_{x}^{-}}{2} , \frac{{φ}_{y}^{+} + {φ}_{y}^{-}}{2} ) - α \frac{{φ}_{x}^{+} - {φ}_{x}^{-}}{2} - β \frac{{φ}_{y}^{+} - {φ}_{y}^{-}}{2}$$

As seen in FIG. 7, a simulated crystalline growth for a structure 700 without LF correction includes increased growth in edge regions 702, such as corner regions. This excess growth in the edge regions 702 represents a simulation error. Simulated crystalline growth for a structure 704 with LF correction accounts for the simulation error and does not include increased growth in edge regions.

As seen in FIG. 8, a simulated crystalline growth for a structure 800 without WENO correction is shown in three views, a 0°/90° cut 800A, a Z-axis cut 800B, and a 45° cut 800C. Inaccurate growth modeling is seen in edge regions 802. This excess growth in the edge regions 802 represents a simulation error. Simulated crystalline growth for a structure 804 shown in a 0°/90° cut 804A, a Z-axis cut 804B, and a 45° cut 804C with LF correction accounts for the simulation error and does not include increased growth in edge regions.

In some embodiments, a total variance diminishing (TVD)² operation is applied using:

∥φ_{i,j}ⁿ⁺¹∥≤∥φ_{i,j}ⁿ∥.

The previous examples illustrate material growth, however, the techniques may also be applied to a material removal process, such as an etch process. For a material etch process, the growth rate is negative and the voxels decrease in number as processing continues.

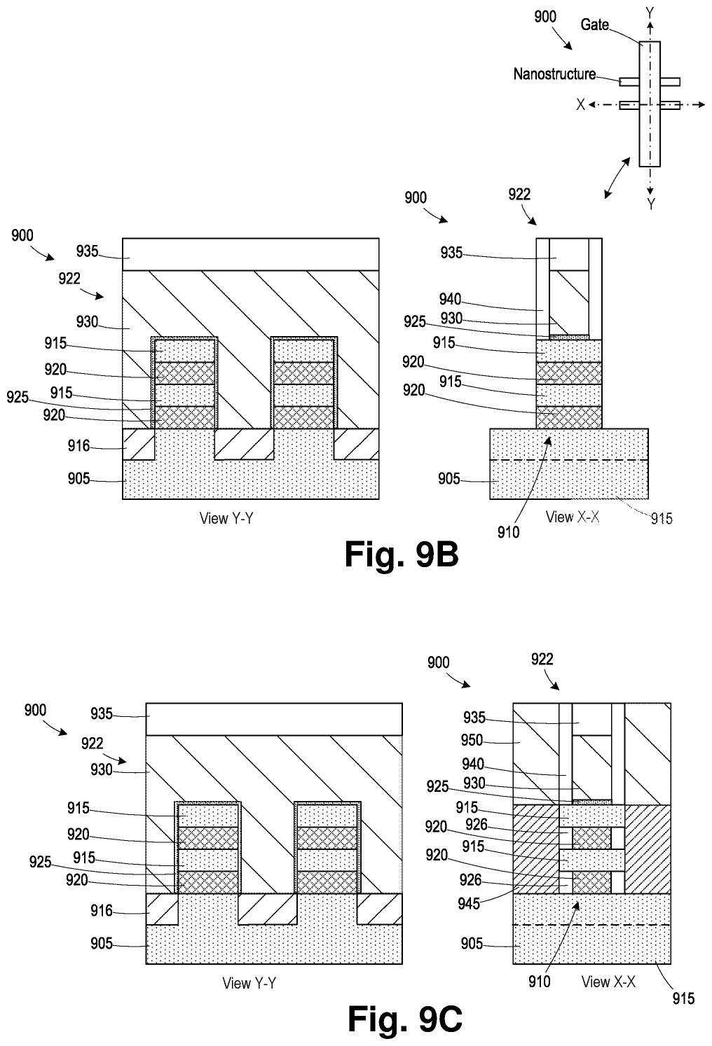

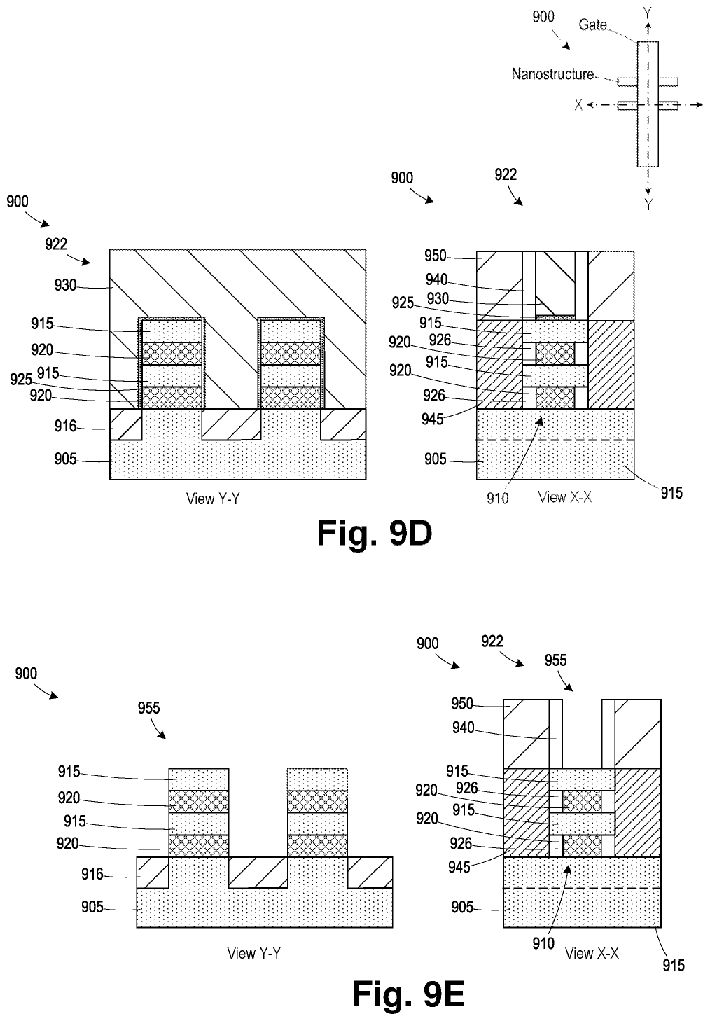

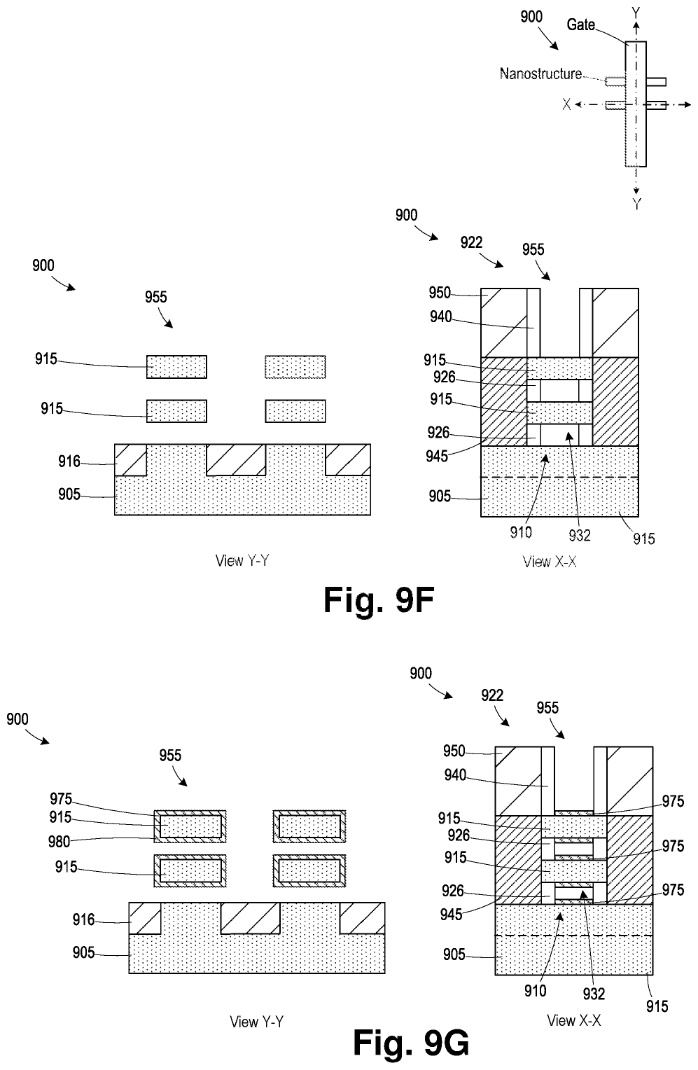

FIGS. 9A-9G are illustrations of a semiconductor arrangement 900 at various stages of fabrication, in accordance with some embodiments. FIGS. 9A-9G include a simplistic plan view showing where various cross-sectional views are taken. Referring to FIG. 9A, the view X-X is a cross-sectional view taken through the semiconductor arrangement 900 in a direction corresponding to a gate fin length direction through fins formed in different regions, and the view Y-Y is a cross-sectional view taken through the semiconductor arrangement 900 in a direction corresponding to a gate length direction through gate structures. Not all aspects of the processing shown in the cross-sectional view will be depicted in the plan view.

Referring to FIG. 9A, a plurality of layers used in the formation of the semiconductor arrangement 900 are illustrated, in accordance with some embodiments. The plurality of layers is formed over a semiconductor layer 905. The semiconductor layer 905 is part of a substrate comprising at least one of an epitaxial layer, a single crystalline semiconductor material such as, but not limited to Si, Ge, SiGe, InGaAs, GaAs, InSb, GaP, GaSb, InAlAs, GaSbP, GaAsSb, InP, a silicon-on-insulator (SOI) structure, a wafer, or a die formed from a wafer. In some embodiments, the semiconductor layer 905 comprises crystalline silicon. The semiconductor arrangement 900 comprises nano-structure based transistors. Nano-structure is used herein to refer to substantially flat, nearly two-dimensional structures, such as sometimes referred to as nano-sheets, as well as structures having two-dimensions that are similar in magnitude, such as sometimes referred to as nano-wires.

In some embodiments, fins 910 are formed by forming a stack of semiconductor material layers and performing an etch process to remove some of the stack of semiconductor material layers, thereby defining the fins 910. The fins 910 comprise semiconductor material layers 915 and sacrificial semiconductor layers 920. The materials of the semiconductor material layers 915 are different than the materials of the sacrificial semiconductor layers 920 to provide etch selectivity and allow removal of the sacrificial semiconductor layers 920.

In some embodiments, the semiconductor material layers 915 comprise the same material composition and the sacrificial semiconductor layers 920 comprise the same material composition. In some embodiments, the semiconductor material layers 915 comprise substantially pure silicon, and the sacrificial semiconductor layers 920 comprise silicon-germanium (SiₓGe₍₁₋ₓ₎ where x ranges from 0.25 to 0.85). The number of semiconductor material layers 915 and sacrificial semiconductor layers 920 may be more than two. The order of the semiconductor material layers 915 and sacrificial semiconductor layers 920 may vary. The thicknesses of the semiconductor material layers 915 and the sacrificial semiconductor layers 920 may vary, and the thicknesses need not be the same.

In some embodiments, during the etch process to remove some of the stack of semiconductor material layers or during a subsequent etch process, a portion of the semiconductor layer 905 is etched to define a recess between the fins 910 and an isolation structure 916, such as a shallow trench isolation (STI) structure, is formed in the recess. In some embodiments, the isolation structure 916 is formed by depositing a dielectric layer between the fins 910 and recessing the dielectric layer to expose at least portions of the sidewalls of the fins 910. The isolation structure 916 may comprise silicon and oxygen or other suitable dielectric materials.

In some embodiments, sacrificial gate structures 922 are formed over the fins 910 and over the isolation structure 916. The sacrificial gate structures 922 comprise a first gate dielectric layer 925 and sacrificial gate electrodes 930. The first gate dielectric layer 925 may comprise a high-k dielectric material. As used herein, the term “high-k dielectric” refers to the material having a dielectric constant, k, greater than or equal to about 3.9, which is the k value of SiO₂. The material of the high-k dielectric layer may be any suitable material. Examples of the material of the high-k dielectric layer include but are not limited to Al₂O₃, HfO₂, ZrO₂, La₂O₃, TiO₂, SrTiO₃, LaAlO₃, Y₂O₃, Al₂OₓN_{y}, HfOₓN_{y}, ZrOₓN_{y}, La₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Each value of x is independently from 0.5 to 3, and each value of y is independently from 0 to 2.

In some embodiments, the first gate dielectric layer 925 comprises a native oxide layer formed by exposure of the semiconductor arrangement 900 to oxygen at various points in the process flow, causing the formation of silicon dioxide on exposed surfaces of the fins 910. An additional layer of dielectric material, such as a high-k dielectric material or other suitable material, may be formed over the native oxide layer to form the first gate dielectric layer 925. According to some embodiments, the sacrificial gate structures 922 are formed by forming a layer of sacrificial material and a hard mask layer over the fins 910 and the isolation structure 916. In some embodiments, a patterning process is performed to pattern the hard mask layer corresponding to the pattern of gate structures to be formed, and an etch process is performed using the patterned hard mask layer to etch the sacrificial layer to define the sacrificial gate electrodes 930. Remaining portions of the hard mask layer form cap layers 935 over the sacrificial gate electrodes 930. Other structures and/or configurations of the sacrificial gate structures 922 are within the scope of the present disclosure.

In some embodiments, sidewall spacers 940 are formed adjacent the sacrificial gate structures 922. In some embodiments, the sidewall spacers 940 are formed by depositing a conformal spacer layer over the sacrificial gate structures 922 and performing an anisotropic etch process to remove portions of the spacer layer positioned on horizontal surfaces of the cap layers 935, the fins 910, and the isolation structure 916. In some embodiments, the sidewall spacers 940 comprise the same material composition as the cap layer 935. In some embodiments, the sidewall spacers 940 comprises nitrogen and silicon or other suitable materials.

Referring to FIG. 9B, the semiconductor material layers 915 and the sacrificial semiconductor layers 920 are etched using the sidewall spacers 940 and the sacrificial gate structures 922 as an etch mask, in accordance with some embodiments. In some embodiments, the semiconductor layer 905 is exposed during an etch process used to etch the semiconductor material layers 915 and the sacrificial semiconductor layers 920.

Referring to FIG. 9C, end spacers 926 are formed adjacent ends of the sacrificial semiconductor layers 920, source/drain regions 945 are formed in the fins 910, and a dielectric layer 950 is formed over the fins 910 and adjacent the sacrificial gate structures 922, in accordance with some embodiments. In some embodiments, after forming the fins 910, an isotropic etch process is performed to recess the sacrificial semiconductor layers 920 to define end cavities. In some embodiments, a deposition process is performed to form a dielectric spacer layer over the fins 910 and an isotropic etch process is performed to remove portions of the dielectric spacer layer outside the end cavities to define the end spacers 926. In some embodiments, the end spacers 926 comprise the same material composition as the sidewall spacers 940. The source/drain regions 945 are formed in the fins 910 after forming the sacrificial gate structures 922 and after forming the end spacers 926. An epitaxial growth process may be performed to form the source/drain regions 945.

In some embodiments, the dielectric layer 950 is formed over the fins 910 and adjacent the sacrificial gate structures 922 after forming the source/drain regions 945. In some embodiments, a portion of the dielectric layer 950 is removed to expose the cap layers 935, such as by planarizing the dielectric layer 950 to expose the cap layers 935. In some embodiments, the dielectric layer 950 comprises silicon dioxide or a low-k material. The dielectric layer 950 may comprise one or more layers of low-k dielectric material. The materials for the dielectric layer 950 comprise at least one of Si, O, C, or H, such as SiCOH and SiOC, or other suitable materials. Organic material such as polymers may be used for the dielectric layer 950. In some embodiments, the dielectric layer 950 comprises one or more layers of a carbon-containing material, organo-silicate glass, a porogen-containing material, or combinations thereof. The dielectric layer 950 may also comprise Nitrogen in some embodiments. The dielectric layer 950 may be formed by using, for example, at least one of low pressure CVD (LPCVD), atomic layer CVD (ALCVD), or a spin-on technology.

Referring to FIG. 9D, the cap layers 935 are removed and heights of the sidewall spacers 940 and the dielectric layer 950 are reduced, in accordance with some embodiments. In some embodiments, a planarization process is performed to remove the cap layers 935 and to reduce the heights of the sidewall spacers 940 and the dielectric layer 950. The planarization process exposes the sacrificial gate electrodes 930. The planarization process may be a continuation of the process performed to planarize the dielectric layer 950.

Referring to FIG. 9E, the sacrificial gate electrodes 930 and the first gate dielectric layer 925 are removed to define gate cavities 955 and expose portions of the fins 910, in accordance with some embodiments. In some embodiments, an etch process is performed to remove the first gate dielectric layer 925 and the sacrificial gate electrodes 930. In some embodiments, the etch process is a wet etch process selective to the material of the sacrificial gate electrodes 930 and the material of the first gate dielectric layer 925.

Referring to FIG. 9F, the sacrificial semiconductor layers 920 are removed to define intermediate cavities 932 between the semiconductor material layers 915, in accordance with some embodiments. In some embodiments, an etch process is performed to remove the sacrificial semiconductor layers 920. In some embodiments, where the sacrificial semiconductor layers 920 comprise the same material composition, a concurrent etch process is performed to remove the sacrificial semiconductor layers 920.

Referring to FIG. 9G, epitaxial layers 975 are formed over the semiconductor material layers 915 in the gate cavity 955, in accordance with some embodiments. In some embodiments, the epitaxial layers 975 comprise silicon.

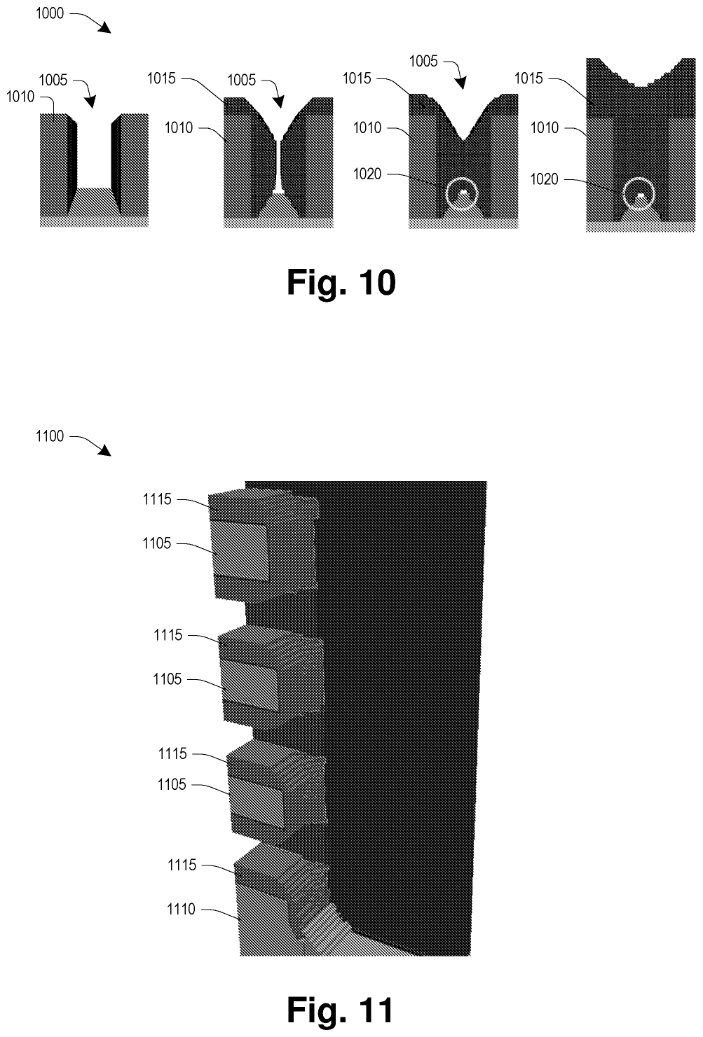

Referring to FIGS. 10 and 11 diagrams illustrating epitaxial structures 1000, 1100 are provided, in accordance with some embodiments. Within the context of the process flow illustrated in FIGS. 9A-9G, the fabrication simulator 102 may be used to simulate crystalline growth of epitaxial layers, such as the source/drain regions 945 shown in FIG. 9C and/or the epitaxial layers 975 shown in FIG. 9G. The structure 1000 corresponds to the source/drain regions 945, and the structure 1100 corresponds to the epitaxial layers 975, albeit with additional semiconductor layers 1105 illustrated in FIG. 11. A model of the surrounding structures may be provided to the fabrication simulator 102 and the epitaxial growth may be simulated based on the geometries of the surrounding structures and the process parameters for forming the epitaxial material.

Referring to FIG. 10, the structure 1000 comprises an opening 1005 formed in a silicon material 1010 in which an epitaxial material 1015 is grown. The epitaxial material 1015 grows on the exposed surfaces of the silicon material 1010. As the epitaxial material 1015 grows, the portions on sidewalls of the opening 1005 merge. In some situations, during the forming of the epitaxial material 1015, reduced precursor gas flow can result in the formation of a void 1020 in a bottom region of the opening 1005. The fabrication simulator 102 may be used to model the growth of the epitaxial material 1015 to predict the efficacy of the filling of the opening 1005 with respect to the formation of voids 1020. Various parameters of the epitaxial growth process may be changed during the simulation by the fabrication simulator 102 to determine an operating recipe, including parameters such as precursor gas flow rate, precursor gas composition, temperature, pressure, or some other operating recipe parameter, that results in a reduced likelihood of void formation. The use of the fabrication simulator 102 allows the operating recipe to be determined without the need for numerous test wafers and destructive testing to identify voids, thereby saving time and reducing cost and resources.

Referring to FIG. 11, the structure 1100 comprises nano-structures 1105 (e.g., corresponding to the semiconductor material layers 915), and a base 1110 on which an epitaxial material 1115 grows. The epitaxial material 1115 grows on the exposed surfaces of the silicon material that defines the nano-structures 1105 and the base 1110. The fabrication simulator 102 may be used to model the growth of the epitaxial material 1115 to predict the growth rate of the epitaxial material 1115. Various parameters of the epitaxial growth process may be changed during the simulation by the fabrication simulator 102 to determine an operating recipe, including parameters such as precursor gas flow rate, precursor gas composition, temperature, pressure, or some other operating recipe parameter, that results in a desired or specified thickness of the epitaxial material 1115. The use of the fabrication simulator 102 allows the operating recipe to be determined without the need for numerous test wafers and destructive testing to determine the thickness of the epitaxial material 1115, thereby saving time and reducing cost and resources.

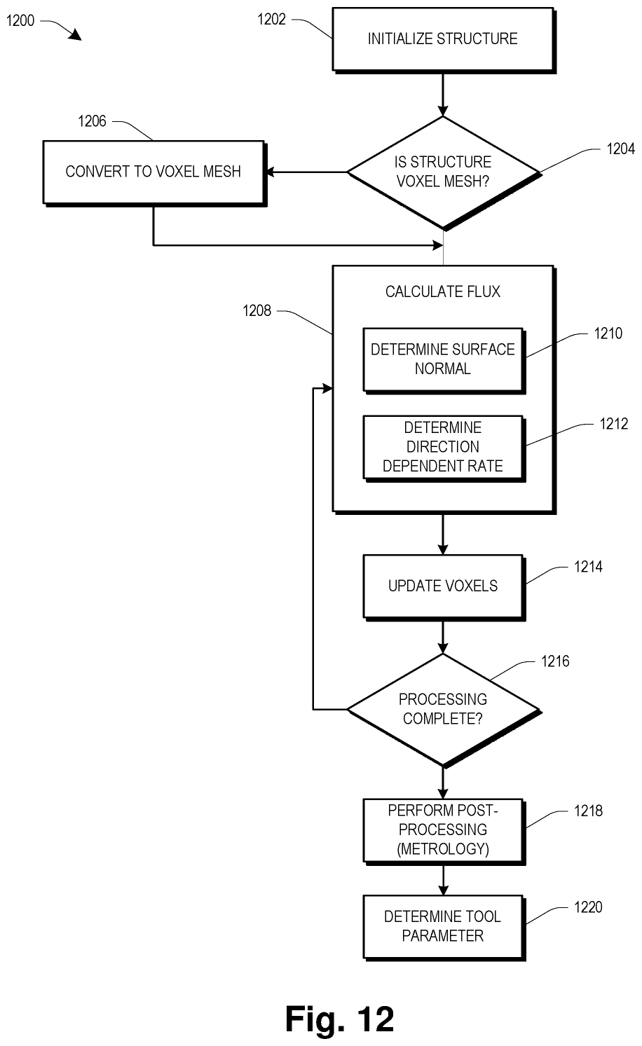

FIG. 12 is a flow diagram of an example method 1200 for simulating material processing, in accordance with some embodiments. At 1202, the fabrication simulator 102 initializes the structure. For example, the structure may be one of the initial structures in FIGS. 10 and 11. At 1204, the fabrication simulator 102 determines whether the structure is a voxel mesh. If the structure is not a voxel mesh at 1204, the fabrication simulator 102 converts the structure to a voxel mesh at 1206. For example, the structure may include at least one of the silicon material 1010 defined as a voxel mesh for simulating the processing in FIG. 10 to grow the epitaxial material 1015 or the nano-structures 1105 and the base 1110 defined as a voxel mesh for simulating the processing in FIG. 11 to grow the epitaxial material 1115.

At 1208, the fabrication simulator 102 calculates the flux to simulate crystalline growth, such as at least one of the growth of the epitaxial material 1015 or the growth of the epitaxial material 1115. Calculating the flux involves an iterative process that includes determining the surface normal direction using the conformal surface mesh 300 at 1210 and determining the direction dependent rate at 1212. The flux may be determined for multiple neighbors and interpolation orders, as illustrated in FIG. 6. Based on the crystalline dependent growth rate, the fabrication simulator 102 updates the voxel mesh 200 at 1214. The fabrication simulator 102 iterates the processes at 1208 and 1210 until processing is complete at 1216. The fabrication simulator 102 performs post-processing at 1218. For example, the post-processing may mimic metrology collection on the simulated structure. For example, the simulated metrology data may include at least one of the presence or absence of voids in the epitaxial material 1015 or the thickness of the epitaxial material 1115. At 1220, the fabrication simulator 102 determines a tool parameter. For example, the tool parameter may include at least one of one or more operating recipe parameters used by the processing tool 104 or one or more control parameters used by the controller 108.

The simulation of material growth by the fabrication simulator 102 allows at least one of operating recipe parameters or control parameter to be determined without requiring device fabrication and metrology, thereby improving fabrication performance metrics and reducing cost and time. The voxel mesh technique simplifies calibration with silicon data and guides process module development. The voxel mesh technique provides a generic framework to simulate semiconductor processing, such as etch, deposition, lithography, or some other processing. The use of a voxel mesh reduces processing time compared to physics based modeling while providing stable results, thereby reducing computer resource usage, computer time, and computer cost and resulting in an improvement to the operation of the computing system.

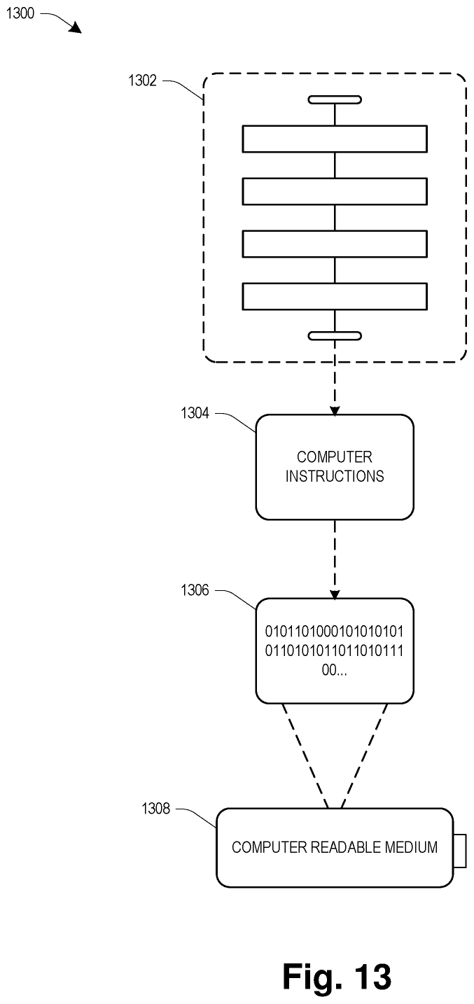

Another embodiment involves a computer-readable medium comprising processor-executable instructions configured to implement one or more of the techniques presented herein. An example embodiment of a computer-readable medium or a computer-readable device that is devised in these ways is illustrated in FIG. 13, wherein the embodiment 1300 comprises a computer-readable medium 1308, such as a CD-R, DVD-R, flash drive, a platter of a hard disk drive, etc., on which is encoded computer-readable data 1306. This computer-readable data 1306, such as binary data comprising a plurality of zero's and one's as shown in the computer-readable data 1306, in turn comprises a set of processor-executable computer instructions 1304 configured to operate according to one or more of the principles set forth herein. In one such embodiment 1300, the processor-executable computer instructions 1304 are configured to perform a method 1302, such as at least some of the example method 1200 of FIG. 12, for example. In another embodiment, the processor-executable computer instructions 1304 are configured to implement a system, such as at least some of the example system 100 of FIG. 1, for example. Many such computer-readable media are devised by those of ordinary skill in the art that are configured to operate in accordance with the techniques presented herein.

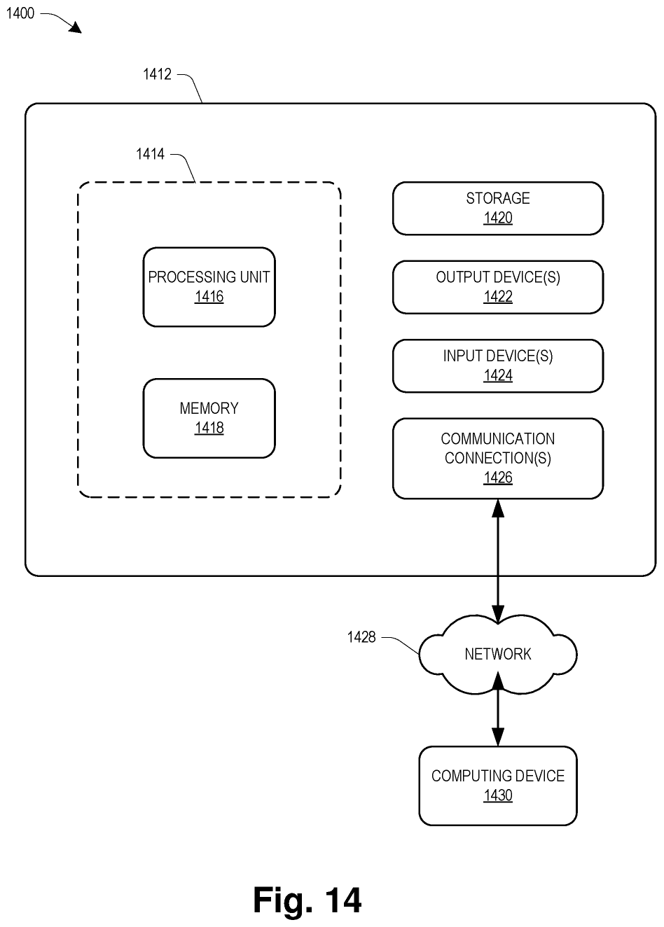

FIG. 14 and the following discussion provide a brief, general description of a suitable computing environment to implement embodiments of one or more of the provisions set forth herein. The operating environment of FIG. 14 is only one example of a suitable operating environment and is not intended to suggest any limitation as to the scope of use or functionality of the operating environment. Example computing devices include, but are not limited to, personal computers, server computers, hand-held or laptop devices, mobile devices, such as mobile phones, Personal Digital Assistants (PDAs), media players, and the like, multiprocessor systems, consumer electronics, mini computers, mainframe computers, distributed computing environments that include any of the above systems or devices, and the like.

Generally, embodiments are described in the general context of “computer readable instructions” being executed by one or more computing devices. Computer readable instructions are distributed via computer readable media as will be discussed below. Computer readable instructions are implemented as program modules, such as functions, objects, Application Programming Interfaces (APIs), data structures, and the like, that perform particular tasks or implement particular abstract data types. Typically, the functionality of the computer readable instructions are combined or distributed as desired in various environments.

FIG. 14 illustrates an example of a system 1400 comprising a computing device 1412 configured to implement one or more embodiments provided herein. In one configuration, computing device 1412 includes at least one processing unit 1416 and memory 1418. Depending on the exact configuration and type of computing device, memory 1418 may be volatile, such as random access memory (RAM), non-volatile, such as read-only memory (ROM), flash memory, etc., or some combination of the two. This configuration is illustrated in FIG. 14 by dashed line 1414. The processing unit 1416 may comprise general and specialized computing devices, such as CPU clusters and hardware accelerator clusters that allow for task optimization and parallel processing. The memory 1418 and storage 1420 may be global memory and storage shared by the clusters.

In other embodiments, device 1412 includes additional features or functionality. For example, device 1412 also includes additional storage such as removable storage or non-removable storage, including, but not limited to, magnetic storage, optical storage, and the like. Such additional storage is illustrated in FIG. 14 by storage 1420. In an embodiment, computer readable instructions to implement one or more embodiments provided herein are in storage 1420. Storage 1420 also stores other computer readable instructions to implement an operating system, an application program, and the like. Computer readable instructions are loaded in memory 1418 for execution by processing unit 1416, for example.

The term “computer readable media” as used herein includes computer storage media. Computer storage media includes volatile and nonvolatile, removable and non-removable media implemented in any method or technology for storage of information such as computer readable instructions or other data. Memory 1418 and storage 1420 are examples of computer storage media. Computer storage media includes, but is not limited to, RAM, ROM, EEPROM, flash memory or other memory technology, CD-ROM, Digital Versatile Disks (DVDs) or other optical storage, magnetic cassettes, magnetic tape, magnetic disk storage or other magnetic storage devices, or any other medium which can be used to store the desired information and which can be accessed by device 1412. Any such computer storage media is part of device 1412.

The term “computer readable media” includes communication media. Communication media typically embodies computer readable instructions or other data in a “modulated data signal” such as a carrier wave or other transport mechanism and includes any information delivery media. The term “modulated data signal” includes a signal that has one or more of its characteristics set or changed in such a manner as to encode information in the signal.

Device 1412 includes input device(s) 1424 such as keyboard, mouse, pen, voice input device, touch input device, infrared cameras, video input devices, or any other input device. Output device(s) 1422 such as one or more displays, speakers, printers, or any other output device are also included in device 1412. Input device(s) 1424 and output device(s) 1422 are connected to device 1412 via a wired connection, wireless connection, or any combination thereof. In an embodiment, an input device or an output device from another computing device are used as input device(s) 1424 or output device(s) 1422 for computing device 1412. Device 1412 also includes communication connection(s) 1426 to facilitate communications with one or more other devices.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

A method includes defining a voxel mesh to represent a structure, defining a conformal surface mesh for the voxel mesh, determining direction dependent rates for voxels in the voxel mesh using the conformal surface mesh, and updating the voxel mesh based on the direction dependent rates. The defining of the conformal surface mesh, the determining of the direction dependent rates, and the updating of the voxel mesh are iterated to simulate a process operation. A parameter of the voxel mesh is determined after simulating the process operation.

A system includes a process tool for fabricating semiconductor wafers and a fabrication simulator. The fabrication simulator is configured to generate a voxel mesh to simulate a process operation of the process tool using an iterative process that updates the voxel mesh during the process operation using direction dependent processing rates for voxels in the voxel mesh, determine a parameter of the voxel mesh after simulating the process operation, and determine a parameter of the process tool based on the parameter of the voxel mesh.

A non-transitory computer-readable storage medium includes computer-executable instructions, which when executed via a processor, perform a method for simulating a process operation of a process tool. The method includes defining a voxel mesh to represent a structure, determining a direction dependent rate for a selected voxel in the voxel mesh based on contributions from nearest neighbors of the selected voxel, and updating the voxel mesh based on the direction dependent rate. The determining of the direction dependent rate and the updating of the voxel mesh are iterated for other voxels in the voxel mesh and for the process operation. A parameter of the voxel mesh is determined after simulating the process operation.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing the claims.

Various operations of embodiments are provided herein. The order in which some or all of the operations are described should not be construed as to imply that these operations are necessarily order dependent. Alternative ordering will be appreciated based upon this description. Further, it will be understood that not all operations are necessarily present in each embodiment provided herein.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used in either the detailed description or the claims, such terms are intended to be inclusive in a manner similar to the term “comprising”.

Also, although the disclosure has been shown and described with respect to one or more implementations, equivalent alterations and modifications will occur based upon a reading and understanding of this specification and the annexed drawings. The disclosure includes all such modifications and alterations and is limited only by the scope of the following claims.

1. A method, comprising:
defining a voxel mesh to represent a structure;
defining a conformal surface mesh for the voxel mesh;
determining direction dependent rates for voxels in the voxel mesh using the conformal surface mesh;
updating the voxel mesh based on the direction dependent rates;
iterating the defining of the conformal surface mesh, the determining of the direction dependent rates, and the updating of the voxel mesh to simulate a process operation; and
determining a parameter of the voxel mesh after simulating the process operation.

2. The method of claim 1, comprising:
determining at least one of an operating recipe parameter or a control parameter for a process tool based on the parameter of the voxel mesh.

3. The method of claim 2, wherein the parameter of the voxel mesh comprises a presence of a void.

4. The method of claim 2, wherein the parameter of the voxel mesh comprises a layer thickness parameter.

5. The method of claim 1, wherein:
updating the voxel mesh comprises updating the voxel mesh using a Hamilton-Jacobi solving technique.

6. The method of claim 1, wherein:
updating the voxel mesh comprises applying a stability operation for edge regions of the voxel mesh.

7. The method of claim 6, wherein the stability operation comprises one or more of a Lax-Friedrichs operation, a weighted non-oscillatory operation, or a total variance diminishing operation.

8. The method of claim 1, wherein:
determining the direction dependent rates comprises determining surface normal directions for the voxels based on the conformal surface mesh.

9. The method of claim 1, wherein:
determining the direction dependent rate for a selected voxel of the voxels comprises determining contributions from nearest neighbors of the selected voxel.

10. A system, comprising:
a process tool for fabricating semiconductor wafers; and
a fabrication simulator configured to generate a voxel mesh to simulate a process operation of the process tool using an iterative process that updates the voxel mesh during the process operation using direction dependent processing rates for voxels in the voxel mesh, determine a parameter of the voxel mesh after simulating the process operation, and determine a parameter of the process tool based on the parameter of the voxel mesh.

11. The system of claim 10, wherein the process operation comprises a material growth process, and the direction dependent processing rates are positive rates.

12. The system of claim 10, wherein the process operation comprises a material removal process, and the direction dependent processing rates are negative rates.

13. The system of claim 10, wherein the fabrication simulator is configured to:
generate a conformal surface mesh for the voxel mesh;
determine a surface normal direction for a selected voxel of the voxels based on the conformal surface mesh; and
determine a direction dependent processing rate for the selected voxel based on the surface normal direction.

14. The system of claim 10, wherein the parameter of the voxel mesh comprises a presence of a void.

15. The system of claim 10, wherein the parameter of the voxel mesh comprises a layer thickness parameter.

16. The system of claim 10, wherein:
the fabrication simulator is configured to update the voxel mesh using a Hamilton-Jacobi representation; and
apply a stability operation for edge regions of the voxel mesh.

17. The system of claim 16, wherein the stability operation comprises one or more of a Lax-Friedrichs operation, a weighted non-oscillatory operation, or a total variance diminishing operation.

18. A non-transitory computer-readable storage medium comprising computer-executable instructions, which when executed via a processor, perform a method for simulating a process operation of a process tool, comprising:
defining a voxel mesh to represent a structure;
determining a direction dependent rate for a selected voxel in the voxel mesh based on contributions from nearest neighbors of the selected voxel;
updating the voxel mesh based on the direction dependent rate;
iterating the determining of the direction dependent rate and the updating of the voxel mesh for other voxels in the voxel mesh and for the process operation; and
determining a parameter of the voxel mesh after simulating the process operation.

19. The non-transitory computer-readable storage medium of claim 18, wherein the method for simulating a process operation of a process tool comprises:
determining a conformal surface mesh for the voxel mesh;
determining a surface normal direction for the selected voxel based on the conformal surface mesh; and
determining the direction dependent rate for the selected voxel based on the surface normal direction.

20. The non-transitory computer-readable storage medium of claim 18, wherein the method for simulating a process operation of a process tool comprises:
updating the voxel mesh using a Hamilton-Jacobi representation; and
applying a stability operation for edge regions of the voxel mesh.
